(19) United States
(12) Patent Application Publication
(10) Pub. No.: US 2024/0188219 A1
(43) Pub. Date: Jun. 6, 2024

(54) METHOD FOR MOUNTING ELECTRONIC COMPONENT AND CIRCUIT BOARD ASSEMBLY

(71) Applicant: JOHNAN Corporation, Uji-shi, Kyoto (JP)

(72) Inventors: Yoshinari MATSUDA, Uji-shi (JP); Takamitsu OKA, Uji-shi (JP); Kazuhiro KITAGAWA, Uji-shi (JP); Yuuichi HIGASHIDANI, Uji-shi (JP); Hidetoshi ARASUNA, Uji-shi (JP)

(73) Assignee: JOHNAN Corporation, Uji-shi, Kyoto (JP)

(21) Appl. No.: 18/285,860

(22) PCT Filed: Mar. 23, 2022
(86) PCT No.: PCT/JP2022/013352

§ 371 Date: Oct. 6, 2023

(30) Foreign Application Priority Data
Apr. 14, 2021 (JP) 2021-068443

(51) Int. Cl. H05K 1/18; H05K 3/12; H05K 3/32

(52) U.S. Cl. CPC H05K 1/181; H05K 3/1283; H05K 3/321; H05K 2201/10886

(57) ABSTRACT

One or more embodiments may include a method for mounting an electronic component to fix an electronic component including an electrode to a circuit board. The method includes applying a first conductive adhesive on a pattern; fixing the electronic component on the circuit board by the first conductive adhesive; applying a second conductive adhesive so as to cover the pattern and at least a half part, on a circuit board side, of each side surface of the electrode; and curing the first conductive adhesive by heating after the fixing and furthermore curing the second conductive adhesive by heating after applying the second conductive adhesive, or curing the first conductive adhesive and the second conductive adhesive by heating after applying the second conductive adhesive.

### TECHNICAL FIELD

The present invention relates to a method for mounting an electronic component and a circuit board assembly on which the electronic component is mounted. Particularly, the present invention relates to a mounting method capable of remarkably improving the bonding strength of the electronic component while using a conductive adhesive, and also to a circuit board assembly made by the mounting method.

### BACKGROUND ART

Conventionally, Pb-based solder has been used for mounting an electronic component on a circuit board (electrical connection). However, Pb-free solder has been more and more preferred, and as a result, the Pb-based solder is being replaced with the Pb-free solder. This Pb-free solder has a melting point higher than that of the Pb-based solder, thus the electronic component having a low heat resistance may be damaged in the soldering process. Furthermore, since the Pb-free solder has a low elasticity compared to the Pb-based solder, the bonding part by the Pb-free solder is more brittle. Thus, cracks are likely to appear especially when a temperature cycling test is conducted.

Recently, in response to size reduction in the electronic device and to high-density mounting of the electronic component, the use of resin components and/or mounting of the electronic component on a flexible board have been increased. Therefore, the soldering process at a high temperature is further inappropriate.

Thus, as an alternative technology of the soldering, a technique also becomes popular, in which an electronic component is mounted on a circuit board using a paste type conductive adhesive (for example, silver paste) obtained by mixing conductive material (conductive filler) for a good electric connection based on silver with a thermosetting binder resin having adhesive function such as epoxy. Since the curing temperature of the conductive adhesive is considerably low compared to the melting point of the solder, it is possible to avoid thermal damage of the electronic component and the like having a low heat resistance (for example, see Patent Documents 1 and 2).

A mounting structure of surface mount components on a circuit board described in Patent Document 1 is a mounting structure in which a lead whose tip side is inclined downward is electrically connected to a number of component land parts on a circuit board by a conductive adhesive. As to the adjacent land parts, the pattern onto which the conductive adhesive is applied so as to include a region corresponding to the tip side of the lead and the pattern onto which the conductive adhesive is applied except for the above region are alternatively repeated. The lead whose tip side is inclined downward is bonded to the land parts on which the conductive adhesive is applied with these patterns.

Also, a conductive adhesive according to Patent Document 2 is a conductive adhesive including conductive particles and a resin, which further contains fluorine and nitrogen.

### PRIOR ART DOCUMENTS

### Patent Documents

[Patent Document 1] JP-UM-A-H05-038951
[Patent Document 2] JP-A-2020-100807

### SUMMARY OF THE INVENTION

### Problem to be Solved by the Invention

FIG. 3 is a schematic cross-sectional view schematically illustrating a circuit board assembly 2 by mounting an electronic component 12 on a circuit board 10 using a general method conventionally known.

In the general method conventionally known as shown in FIG. 3, a Thermosetting conductive adhesive 21 is applied on a pattern 11 provided on a circuit board 10 by, for example, a dispenser or screen printing. After positioning and placing an electronic component 12 such that an electrode 12a is positioned on the Thermosetting conductive adhesive 21, all the structure is heated. Thus, the conductive adhesive 21 is cured, and the electrode 12a is mechanically bonded and electrically connected to the pattern 11.

However, since the conductive adhesive 21 does not have wettability that the solder paste has, there is almost no spreading of the conductive adhesive 21 over the side surface and the upper surface of the electrode 12a. As a result, the electrode 12a is connected only by its bottom surface and lower corner parts, which often leads to insufficient bonding strength. In order to compensate the lack of bonding strength, it is possible to use, for example, protective/reinforcing material or to seal the electronic component 12 by resin so as to ensure the necessary bonding strength. In return for this compensation, the mounting process may be complicated, or the space for mounting may be difficult to reduce, which results in increase of mounting costs.

In order to solve the above problems, improvement studies on the materials for the conductive filler and the binder resin and the mixing ratio thereof as the conductive adhesive have been exclusively conducted until now, as shown in Patent Document 2. In contrast, Patent Document 1 is an invention to prevent adjacent land parts on a circuit board from making contact with each other when an electronic component (such as an IC and an LSI) is mounted on the circuit board by a conductive adhesive. Thus, Patent Document 1 originally has a very different type of problem to be solved and a different technical idea.

In consideration of the problems in the conventional art, an object of the present invention is to provide a method for mounting an electronic component, which is capable of remarkably improving the bonding strength of the electronic component while using a conductive adhesive. Also, an object of the present invention is to provide a circuit board assembly made by the above mounting method.

### Means for Solving the Problem

In order to achieve the above object, a method for mounting an electronic component according to one aspect of the present invention is to fix an electronic component including at least one electrode to a circuit board on which at least one pattern corresponding to the at least one electrode is provided. The method includes: a step of applying a first thermosetting conductive adhesive on the at least one pattern; a step of fixing the electronic component by the first thermosetting conductive adhesive by positioning and placing the electronic component on the circuit board such that the at least one electrode corresponds to the at least one pattern; a step of applying a second thermosetting conductive adhesive so as to cover the at least one pattern and at least a half part, on a circuit board side, of each side surface of the at least one electrode; and a step of curing the first thermosetting conductive adhesive by heating after the fixing step and furthermore curing the second thermosetting conductive adhesive by heating after the step of applying the second thermosetting conductive adhesive, or a step of curing the first thermosetting conductive adhesive and the second thermosetting conductive adhesive by heating after the step of applying the second thermosetting conductive adhesive.

Here, the first conductive adhesive may be the same adhesive as the second conductive adhesive. Alternatively, the conductivity of the second conductive adhesive may be higher than the conductivity of the first conductive adhesive. Regarding the curing step, for example, the heating after the fixing step and the heating after the step of applying the second conductive adhesive may be performed separately so that the first conductive adhesive is cured by the first heating and the second conductive adhesive is cured by the second heating. Alternatively, the first conductive adhesive and the second conductive adhesive may be cured at one time by the heating after the step of applying the second conductive adhesive.

With the mounting method having the configuration as described above, it is possible to considerably improve the bonding strength of the electronic component while using the conductive adhesive. Thus, it is possible to prevent the electronic component from falling off, which results in no protective/reinforcing material being required. Accordingly, it is possible to improve impact resistance of the circuit board assembly on which the electronic component is mounted. When the conductivity of the second conductive adhesive is higher than the conductivity of the first conductive adhesive, it is possible to further reduce the electrical resistance of the realized electrical connection.

Also, a method for mounting an electronic component according to another aspect of the present invention is to fix an electronic component including at least one electrode to a circuit board on which at least one pattern corresponding to the at least one electrode is provided. The method includes: a step of applying a non-conductive adhesive to an area on the circuit board other than an area where the at least one pattern is provided; a step of temporarily fixing the electronic component by the non-conductive adhesive by positioning and placing the electronic component on the circuit board such that the at least one electrode corresponds to the at least one pattern; a step of applying a thermosetting conductive adhesive so as to cover the at least one pattern and at least a half part, on a circuit board side, of each side surface of the at least one electrode; and a step of curing the thermosetting conductive adhesive by heating.

With the mounting method having the configuration as described above, it is possible to considerably improve the bonding strength of the electronic component while using the conductive adhesive. Thus, it is possible to prevent the electronic component from falling off, which results in no protective/reinforcing material being required. Accordingly, it is possible to improve impact resistance of the circuit board assembly on which the electronic component is mounted.

Furthermore, a method for mounting an electronic component according to another aspect of the present invention is to fix an electronic component including at least one electrode to a circuit board on which at least one pattern corresponding to the at least one electrode is provided. The method includes: a step of applying a thermosetting conductive adhesive so as to cover the at least one pattern and at least a half part, on a circuit board side, of each side surface of the at least one electrode; and a step of curing the thermosetting conductive adhesive by heating.

With the mounting method having the configuration as described above, it is possible to considerably improve the bonding strength of the electronic component while using the conductive adhesive. Thus, it is possible to prevent the electronic component from falling off, which results in no protective/reinforcing material being required. Accordingly, it is possible to improve impact resistance of the circuit board assembly on which the electronic component is mounted.

A circuit board assembly according to another aspect of the present invention includes: an electronic component including at least one electrode; and a circuit board on which at least one pattern corresponding to the at least one electrode is provided. The electronic component is positioned and placed on the circuit board such that the at least one electrode corresponds to the at least one pattern. The at least one pattern and a half part, on a circuit board side, of each side surface of the at least one electrode are covered by a cured conductive adhesive.

With the circuit board assembly having the configuration as described above, it is possible to considerably improve the bonding strength of the electronic component while using the conductive adhesive. Thus, it is possible to prevent the electronic component from falling off, which results in no protective/reinforcing material being required. Accordingly, it is possible to improve impact resistance of the circuit board assembly on which the electronic component is mounted.

### Effects of the Invention

With the method for mounting an electronic component and a circuit board assembly made by the mounting method, it is possible to considerably improve the bonding strength of the electronic component while using the conductive adhesive. Thus, it is possible to prevent the electronic component from falling off, which results in no protective/reinforcing material being required. Accordingly, it is possible to improve impact resistance of the circuit board assembly on which the electronic component is mounted.

### BRIEF DESCRIPTION OF THE DRAWINGS

FIG. 1 is a cross-sectional view schematically illustrating a circuit board assembly 1 made by mounting an electronic component 12 on a circuit board 10 using a method for mounting an electronic component according to Embodiment 1 of the present invention.

FIG. 2 is a cross-sectional view schematically illustrating a circuit board assembly 1A made by mounting the electronic component 12 on the circuit board using a method for mounting an electronic component according to Embodiment 2 of the present invention.

FIG. 3 is a cross-sectional view schematically illustrating a circuit board assembly 2 made by mounting the electronic component 12 on the circuit board 10 using the general method conventionally known.

### MODE FOR CARRYING OUT THE INVENTION

Hereinafter, embodiments of the present invention will be described with reference to the drawings.

### Embodiment 1

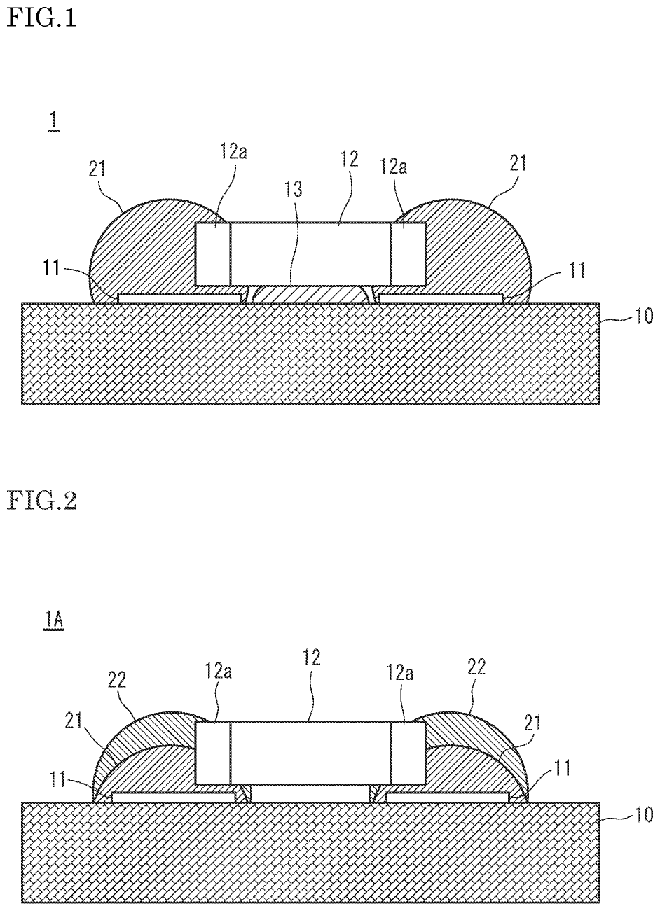

FIG. 1 is a cross-sectional view schematically illustrating a circuit board assembly 1 made by mounting an electronic component 12 on a circuit board 10 using a method for mounting an electronic component according to Embodiment 1 of the present invention.

As shown in FIG. 1, the chip-shaped electronic component 12 has, at each end thereof, an electrode 12a. Patterns 11 are respectively formed on the flat plate-shaped circuit board 10 so as to correspond to the electrodes 12a. The electronic component 12 is not necessarily limited to a surface mount technology (SMT) type chip component.

Hereinafter, the method for mounting the electronic component according to Embodiment 1 is described. Note that this method is not necessarily required to be applied to all of the electronic components 12 to be mounted on the circuit board 10. The electronic component 12 to which the method is applied may be determined in consideration of the bonding strength necessary for fall prevention and/or the required time for mounting, for every electronic components 12 having different sizes or shapes.

(1.1) Step of Applying Non-Conductive Adhesive 13 onto Circuit Board 10

Before mounting the electronic component 12 on the circuit board 10, the Non-Conductive Adhesive 13 is applied to a part other than the Patterns 11 on the circuit board 10, for example, to a part corresponding to the area directly under the electronic component 12 between two Patterns 11 in order to temporarily fix the electronic component 12.

### (1.2) Step of Positioning and Placing Electronic Component 12 on Circuit Board 10 and Thus Temporarily Fixing Electronic Component 12 to Circuit Board 10

The electronic component 12 is positioned such that the electrodes 12a at both ends of the electronic component 12 respectively correspond to the two Patterns 11. Then, the electronic component 12 is placed on the circuit board 10. Thus, the electronic component 12 is temporarily fixed by the Non-Conductive Adhesive 13 applied in step (1.1) described above.

### (1.3) Step of Applying Thermosetting Conductive Adhesive 21

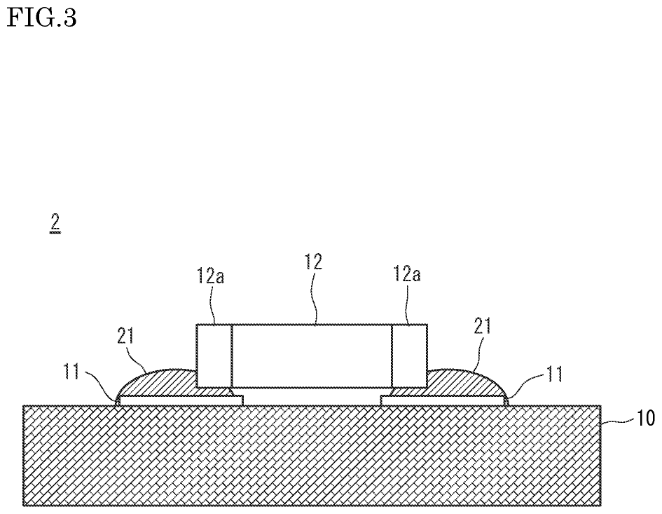

The Thermosetting conductive adhesive 21 is applied, by a dispenser, so as to cover almost all the Patterns 11 and the electrodes 12a. However, the substantially entire part of each electrode 12a is not necessarily required to be covered. By applying a significantly large amount of Thermosetting conductive adhesive 21 compared to the case where the conventional method is used as shown in FIG. 3, a correspondingly higher effect can be expected. For example, it is preferable to apply the Thermosetting conductive adhesive 21 so as to reach the upper surface of the electrode 12a or to almost cover at least the lower half (half part on the side of the circuit board 10) of each side surface of the electrode 12a (in the case of the right electrode 12a shown in FIG. 1, the front side surface, the right side surface and the far side surface). The conductive adhesive 21 may be applied once, or may be applied multiple times. As to the dispenser, a non-contact jet dispenser is preferably used.

### (1.4) Step of Curing Conductive Adhesive 21 by Heating

The whole structure is heated so as to cure the conductive adhesive 21. Thus, the mechanical bonding and the electrical connection between the electrodes 12a of the electronic component 12 and the Patterns 11 on the circuit board 10 are realized.

By the above-described method for mounting the electronic component according to Embodiment 1, it is possible to considerably improve the bonding strength of the electronic component 12. Since the falling-off of the electronic component 12 can be prevented, the protective/reinforcing material is not needed. Thus, it is possible to improve the impact resistance of the circuit board assembly 1 on which the electronic component 12 is mounted.

### Embodiment 2

FIG. 2 is a cross-sectional view schematically illustrating a circuit board assembly 1A made by mounting the electronic component 12 on the circuit board 10 using a method for mounting an electronic component according to Embodiment 2 of the present invention. The same reference signs are given to the same components as those in Embodiment 1. Hereinafter, the different points from Embodiment 1 are mainly described. Similarly to Embodiment 1, this method is not necessarily required to be applied to all the electronic components 12 to be mounted on the circuit board 10.

Hereinafter, the method for mounting the electronic component according to Embodiment 2 is described.

(2.1) Step of Applying Thermosetting Conductive Adhesive 21 onto Patterns 11

In order to fix the electronic component 12 to the circuit board 10, the Thermosetting conductive adhesive 21 is applied to the Patterns 11 by a dispenser or screen printing.

### (2.2) Step of Positioning and Placing Electronic Component 12 on Circuit Board 10 and Thus Fixing Electronic Component 12 to Circuit Board 10

The electronic component 12 is positioned such that the electrodes 12a at both ends of the electronic component 12 respectively correspond to the two Patterns 11. Then, the electronic component 12 is placed on the circuit board 10. Thus, the electronic component 12 is fixed by the conductive adhesive 21 applied in step (2.1) described above.

### (2.3) Step of Curing Conductive Adhesive 21 by Heating

The whole structure is heated so as to cure the conductive adhesive 21. Thus, the mechanical bonding and the electrical connection between the electrodes 12a of the electronic component 12 and the Patterns 11 on the circuit board 10 are realized.

### (2.4) Step of Further Applying Thermosetting Conductive Adhesive 22

A thermosetting conductive adhesive 22 is further applied, by the dispenser, so as to cover almost all the Patterns 11 and the electrodes 12a to which the conductive adhesive 21 was already applied and cured. However, the substantially entire part of each electrode 12a is not necessarily required to be covered. By applying a significantly large amount of thermosetting conductive adhesive 22 compared to the case where the conventional method is used as shown in FIG. 3, a correspondingly higher effect can be expected. For example, it is preferable to apply the thermosetting conductive adhesive 22 so as to reach the upper surface of the electrode 12a or to almost cover at least the lower half (half part on the side of the circuit board 10) of each side surface of the electrode 12a (in the case of the right electrode 12a shown in FIG. 2, the front side surface, the right side surface and the far side surface).

Here, the conductive adhesive 22 may be the same as the conductive adhesive 21 applied in step (2.1) described above, or may be a conductive adhesive having higher conductivity. In this way, it is possible to further reduce the electrical resistance of the realized electrical connection compared to the case where the conductive adhesive 21 is the same as the conductive adhesive 22. The conductive adhesive 22 may be applied once, or may be applied multiple times. As to the dispenser, a non-contact jet dispenser is preferably used.

### (2.5) Step of Curing Conductive Adhesive 22 by Heating

The whole structure is re-heated so as to cure the conductive adhesive 22. Thus, the mechanical bonding and the electrical connection between the electrodes 12a of the electronic component 12 and the Patterns 11 are realized.

By the above-described method for mounting the electronic component according to Embodiment 2, it is possible to considerably improve the bonding strength of the electronic component 12. Since the falling-off of the electronic component 12 can be prevented, the protective/reinforcing material is not needed. Thus, it is possible to improve the impact resistance of the circuit board assembly 1 on which the electronic component 12 is mounted. Unlike Embodiment 1, in this method there is no need to perform the step of applying the Non-Conductive Adhesive 13 to the circuit board 10 and the step of placing and temporarily fixing the electronic component 12.

Step (2.3) described above may be omitted, and the conductive adhesive 21 and the conductive adhesive 22 may be cured at once in step (2.5). In this way, the steps can be simplified, which results in reduction in total time for mounting.

### OTHER EMBODIMENTS

As shown in step (1.3) of Embodiment 1 and in step (2.4) of Embodiment 2, the essential feature of the present invention is to apply the Thermosetting conductive adhesive 21 and/or the thermosetting conductive adhesive 22 so as to cover the pattern 11 and at least a substantially lower half of each side surface of the electrode 12a, and then to cure the conductive adhesive 21 and/or the conductive adhesive 22 by heating. As to the method for fixing or temporarily fixing the electronic component 12 to the circuit board 10, steps (1.1) and (1.2) of Embodiment 1 as well as steps (2.1) to (2.3) of Embodiment 2 are exemplarily described. However, the fixing method is not limited thereto.

Also, the above-described Embodiment 1 and Embodiment 2 may be appropriately combined. For example, before performing step (2.1) of Embodiment 2, steps (1.1) and (1.2) of Embodiment 1 may be sequentially performed so as to temporarily fix the electronic component 12 to the circuit board 10 by the Non-Conductive Adhesive 13. After that, the step of fixing the electronic component 12 by the conductive adhesive 21 and the step of reinforcing the mechanical bonding as well as the electrical connection between the electrodes 12a and the Patterns 11 by the conductive adhesive 22 may be performed.

The present invention may be embodied in other forms without departing from the gist or essential characteristics thereof. The foregoing embodiments are therefore to be considered in all respects as illustrative and not limiting. The scope of the invention is indicated by the appended claims rather than by the foregoing description, and all modifications and changes that come within the meaning and range of equivalency of the claims are intended to be embraced therein.

### INDUSTRIAL APPLICABILITY

The present invention is applicable to a method for mounting an electronic component using a conductive adhesive and also to a circuit board assembly made by using a conductive adhesive. Specifically, it is suitably applied to mounting of electronic components on inexpensive substrates made of, for example, polyethylene terephthalate (PET) and polycarbonate (PC), or on thin and flexible films and the like. Furthermore, the present invention is suitably applied to in-mold electronics and wearable devices.

This application claims priority based on Patent Application No. 2021-068443 filed in Japan on Apr. 14, 2021. The entire contents thereof are hereby incorporated in this application by reference.

### DESCRIPTION OF THE REFERENCE NUMERALS

1 Circuit board assembly (by method for mounting electronic component according to Embodiment 1)
1A Circuit board assembly (by method for mounting electronic component according to Embodiment 2)
2 Circuit board assembly (by conventional method)
10 Circuit board
11 Pattern
12 Electronic component
12a Electrode
13 Adhesive (for temporarily fixing: non-conductive type)
21 First conductive adhesive
22 Second conductive adhesive

1. A method for mounting an electronic component to fix an electronic component including at least one electrode to a circuit board on which at least one pattern corresponding to the at least one electrode is provided, the method comprising:
applying a first thermosetting conductive adhesive on the at least one pattern;
fixing the electronic component by the first thermosetting conductive adhesive by positioning and placing the electronic component on the circuit board such that the at least one electrode corresponds to the at least one pattern;
applying a second thermosetting conductive adhesive so as to cover the at least one pattern and at least a half part, on a circuit board side, of each side surface of the at least one electrode; and
curing the first thermosetting conductive adhesive by heating after the fixing and furthermore curing the second thermosetting conductive adhesive by heating after applying the second thermosetting conductive adhesive, or curing the first thermosetting conductive adhesive and the second thermosetting conductive adhesive by heating after applying the second thermosetting conductive adhesive.

2. The method for mounting an electronic component according to claim 1, wherein
the first thermosetting conductive adhesive is a same adhesive as the second thermosetting conductive adhesive.

3. A method for mounting an electronic component to fix an electronic component including at least one electrode to a circuit board on which at least one pattern corresponding to the at least one electrode is provided, the method comprising:
applying a non-conductive adhesive to an area on the circuit board other than an area where the at least one pattern is provided;
temporarily fixing the electronic component by the non-conductive adhesive by positioning and placing the electronic component on the circuit board such that the at least one electrode corresponds to the at least one pattern;
applying a thermosetting conductive adhesive so as to cover the at least one pattern and at least a half part, on a circuit board side, of each side surface of the at least one electrode; and
curing the thermosetting conductive adhesive by heating.

4. A method for mounting an electronic component to fix an electronic component including at least one electrode to a circuit board on which at least one pattern corresponding to the at least one electrode is provided, the method comprising:
applying a thermosetting conductive adhesive so as to cover the at least one pattern and at least a half part, on a circuit board side, of each side surface of the at least one electrode; and
curing the thermosetting conductive adhesive by heating.

5. A circuit board assembly comprising:
an electronic component including at least one electrode; and
a circuit board on which at least one pattern corresponding to the at least one electrode is provided, wherein
the electronic component is positioned and placed on the circuit board such that the at least one electrode corresponds to the at least one pattern, and
the at least one pattern and a half part, on a circuit board side, of each side surface of the at least one electrode are covered by a cured conductive adhesive.
